(19) United States
(12) Patent Application Publication
(10) Pub. No.: US 2026/0237454 A1
(43) Pub. Date: Aug. 13, 2026

(54) FAIL RECOVERY METHOD, MEMORY STORAGE DEVICE AND MEMORY CONTROL CIRCUIT UNIT

(71) Applicant: PHISON ELECTRONICS CORP., Miaoli (TW)

(72) Inventors: Yu-Siang Yang, New Taipei City (TW); Ting-Chien Zhan, Hsinchu City (TW); Yi-Jie Wu, Miaoli County (TW); Yu-Cheng Hsu, Yilan County (TW)

(73) Assignee: PHISON ELECTRONICS CORP., Miaoli (TW)

(21) Appl. No.: 19/064,707

(22) Filed: Feb. 27, 2025

(30) Foreign Application Priority Data
Feb. 11, 2025 (TW) 114105089

(51) Int. Cl. G11C 29/00; G11C 29/52

(52) U.S. Cl. CPC G11C 29/76; G11C 29/52

(57) ABSTRACT

A fail recovery method, a memory storage device, and a memory control circuit unit are provided. The fail recovery method includes: in response to a first operation corresponding to a first physical unit failing, determining whether a current retry count is less than a predetermined count, in which the current retry count is used to represent a number of times an erase retry operation is performed on the first physical unit; in response to the current retry count being less than the predetermined count, performing the erase retry operation on the first physical unit; determining whether the erase retry operation is successful; and in response to the erase retry operation being successful, associating the first physical unit with a spare region.

### CROSS-REFERENCE TO RELATED APPLICATION

This application claims the priority benefit of Taiwan application no. 114105089, filed on Feb. 11, 2025. The entirety of the above-mentioned patent application is hereby incorporated by reference herein and made a part of this specification.

### BACKGROUND

### Technical Field

The disclosure relates to a memory management technology, and particularly relates to a fail recovery method, a memory storage device, and a memory control circuit unit.

### Description of Related Art

Portable electronic devices such as mobile phones and notebook computers have grown rapidly in the past few years, which has led to a rapid increase in consumer demand for storage media. Since a rewritable non-volatile memory module (such as a flash memory) has characteristics such as data non-volatility, power-saving, small size, and lack of mechanical structures, the rewritable non-volatile memory module is very suitable to be built into the various portable electronic devices provided above.

Generally speaking, during the access process of a memory storage device, when an error occurs in a physical unit, the physical unit may be recorded in a bad block table. Afterward, the physical unit may no longer be accessed. However, some physical units where errors occur may continue to be used for accessing data in actual usage scenarios. For example, the data stored by these physical units may be successfully decoded in an error correction process in actual usage scenarios.

### SUMMARY

In view of this, the disclosure provides a fail recovery method, a memory storage device, and a memory control circuit unit, which may further analyze whether the physical unit where an error occurs may continue to be used for accessing data, thereby improving the access performance of the rewritable non-volatile memory module.

An exemplary embodiment of the disclosure provides a fail recovery method for a rewritable non-volatile memory module. The rewritable non-volatile memory module includes a plurality of physical units. The fail recovery method includes: in response to a first operation corresponding to a first physical unit failing, determining whether a current retry count is less than a predetermined count, wherein the current retry count is used to represent a number of times an erase retry operation is performed on the first physical unit; in response to the current retry count being less than the predetermined count, performing the erase retry operation on the first physical unit; determining whether the erase retry operation is successful; and in response to the erase retry operation being successful, associating the first physical unit with a spare region.

According to an exemplary embodiment of the disclosure, the fail recovery method further includes: in response to the erase retry operation failing, determining again whether the current retry count is less than the predetermined count.

According to an exemplary embodiment of the disclosure, the fail recovery method further includes: in response to the current retry count reaching the predetermined count, obtaining a fail bit count of the first physical unit based on a threshold voltage; determining whether the fail bit count is less than a predetermined bit count; and in response to the fail bit count not being less than the predetermined bit count, updating the first physical unit as a second-level error in a bad block table.

According to an exemplary embodiment of the disclosure, the fail recovery method further includes: in response to the fail bit count being less than the predetermined bit count, associating the first physical unit with the spare region again.

According to an exemplary embodiment of the disclosure, the fail recovery method further includes: in response to the first operation being a multi-plane operation, determining whether the number of a first physical plane is greater than a predetermined number, wherein the first physical plane is a physical plane where an error occurs; in response to the number being greater than the predetermined number, determining whether the current retry count is less than the predetermined count; and in response to the current retry count being less than the predetermined count, performing the erase retry operation on the first physical unit belonging to the first physical plane, wherein the erase retry operation is a single plane operation.

According to an exemplary embodiment of the disclosure, the fail recovery method further includes: in response to the number not being greater than the predetermined number, updating the first physical unit as the second-level error in the bad block table.

According to an exemplary embodiment of the disclosure, the fail recovery method further includes: in response to the current retry count not being less than the predetermined count, updating the first physical unit as the second-level error in the bad block table.

According to an exemplary embodiment of the disclosure, the fail recovery method further includes: in response to the first operation failing, recording the first physical unit as a first-level error in the bad block table.

An exemplary embodiment of the disclosure further provides a memory storage device, including a connection interface unit, a rewritable non-volatile memory module, and a memory control circuit unit. The connection interface unit is coupled to a host system. The memory control circuit unit is coupled to the connection interface unit and the rewritable non-volatile memory module. The rewritable non-volatile memory module includes a plurality of physical units. In response to a first operation corresponding to a first physical unit failing, the memory control circuit unit is configured to determine whether a current retry count is less than a predetermined count, wherein the current retry count is used to represent a number of times an erase retry operation is performed on the first physical unit. In response to the current retry count being less than the predetermined count, the memory control circuit unit is further configured to perform the erase retry operation on the first physical unit. The memory control circuit unit is further configured to determine whether the erase retry operation is successful. In response to the erase retry operation being successful, the memory control circuit unit is further configured to associate the first physical unit with a spare region.

According to an exemplary embodiment of the disclosure, in response to the erase retry operation failing, the memory control circuit unit is further configured to determine again whether the current retry count is less than the predetermined count.

According to an exemplary embodiment of the disclosure, in response to the current retry count reaching the predetermined count, the memory control circuit unit is further configured to obtain a fail bit count of the first physical unit based on a threshold voltage. The memory control circuit unit is further configured to determine whether the fail bit count is less than a predetermined bit count. In response to the fail bit count not being less than the predetermined bit count, the memory control circuit unit is further configured to update the first physical unit as a second-level error in a bad block table.

According to an exemplary embodiment of the disclosure, in response to the fail bit count being less than the predetermined bit count, the memory control circuit unit is further configured to associate the first physical unit with the spare region.

According to an exemplary embodiment of the disclosure, in response to the first operation being a multi-plane operation, the memory control circuit unit is further configured to determine whether the number of a first physical plane is greater than a predetermined number, wherein the first physical plane is a physical plane where an error occurs. In response to the number being greater than the predetermined number, the memory control circuit unit is further configured to determine whether the current retry count is less than the predetermined count. In response to the current retry count being less than the predetermined count, the memory control circuit unit is further configured to perform the erase retry operation on the first physical unit belonging to the first physical plane, wherein the erase retry operation is a single plane operation.

According to an exemplary embodiment of the disclosure, in response to the number not being greater than the predetermined number, the memory control circuit unit is further configured to update the first physical unit as the second-level error in the bad block table.

According to an exemplary embodiment of the disclosure, in response to the current retry count not being less than the predetermined count, the memory control circuit unit is further configured to update the first physical unit as the second-level error in the bad block table.

According to an exemplary embodiment of the disclosure, in response to the first operation failing, the memory control circuit unit is further configured to record the first physical unit as a first-level error in the bad block table.

An exemplary embodiment of the disclosure further provides a memory control circuit unit for controlling a rewritable non-volatile memory module. The rewritable non-volatile memory module includes a plurality of physical units. The memory control circuit unit includes a host interface, a memory interface, and a memory management circuit. The host interface is coupled to a connection interface unit. The memory interface is coupled to the rewritable non-volatile memory module. The memory management circuit is coupled to the host interface and the memory interface. In response to a first operation corresponding to a first physical unit failing, the memory management circuit is configured to determine whether a current retry count is less than a predetermined count, wherein the current retry count is used to represent a number of times an erase retry operation is performed on the first physical unit. In response to the current retry count being less than the predetermined count, the memory management circuit is further configured to perform the erase retry operation on the first physical unit. The memory management circuit is further configured to determine whether the erase retry operation is successful. In response to the erase retry operation being successful, the memory management circuit is further configured to associate the first physical unit with a spare region.

According to an exemplary embodiment of the disclosure, in response to the erase retry operation failing, the memory management circuit is further configured to determine again whether the current retry count is less than the predetermined count.

According to an exemplary embodiment of the disclosure, in response to the current retry count reaching the predetermined count, the memory management circuit is further configured to obtain a fail bit count of the first physical unit based on a threshold voltage. The memory management circuit is further configured to determine whether the fail bit count is less than a predetermined bit count. In response to the fail bit count not being less than the predetermined bit count, the memory management circuit is further configured to update the first physical unit as a second-level error in a bad block table.

According to an exemplary embodiment of the disclosure, in response to the fail bit count being less than the predetermined bit count, the memory management circuit is further configured to associate the first physical unit with the spare region.

According to an exemplary embodiment of the disclosure, in response to the first operation being a multi-plane operation, the memory management circuit is further configured to determine whether the number of a first physical plane is greater than a predetermined number, wherein the first physical plane is a physical plane where an error occurs. In response to the number being greater than the predetermined number, the memory management circuit is further configured to determine whether the current retry count is less than the predetermined count. In response to the current retry count being less than the predetermined count, the memory management circuit is further configured to perform the erase retry operation on the first physical unit belonging to the first physical plane, wherein the erase retry operation is a single plane operation.

According to an exemplary embodiment of the disclosure, in response to the number not being greater than the predetermined number, the memory management circuit is further configured to update the first physical unit as the second-level error in the bad block table.

According to an exemplary embodiment of the disclosure, in response to the current retry count not being less than the predetermined count, the memory management circuit is further configured to update the first physical unit as the second-level error in the bad block table.

According to an exemplary embodiment of the disclosure, in response to the first operation failing, the memory management circuit is further configured to record the first physical unit as a first-level error in the bad block table.

Based on the foregoing, the fail recovery method, memory storage device, and memory control circuit unit of the disclosure may further analyze the physical unit where an error occurs to determine whether the physical unit may continue to be used for accessing data, thereby maintaining data correctness while improving the access performance of the rewritable non-volatile memory module.

### BRIEF DESCRIPTION OF THE DRAWINGS

FIG. 1 is a schematic diagram showing a host system, a memory storage device, and an input/output (I/O) device according to an exemplary embodiment of the disclosure.

FIG. 2 is a schematic diagram showing a host system, a memory storage device, and an I/O device according to an exemplary embodiment of the disclosure.

FIG. 3 is a schematic diagram showing a host system and a memory storage device according to an exemplary embodiment of the disclosure.

FIG. 4 is a schematic diagram showing a memory storage device according to an exemplary embodiment of the disclosure.

FIG. 5 is a schematic diagram showing a memory control circuit unit according to an exemplary embodiment of the disclosure.

FIG. 6 is a schematic diagram showing management of a rewritable non-volatile memory module according to an exemplary embodiment of the disclosure.

FIG. 7 is a flowchart of a fail recovery method according to an exemplary embodiment of the disclosure.

FIG. 8 is a flowchart of a fail recovery method according to an exemplary embodiment of the disclosure.

FIG. 9 is a flowchart of a fail recovery method according to an exemplary embodiment of the disclosure.

FIG. 10 is a flowchart of a fail recovery method according to an exemplary embodiment of the disclosure.

FIG. 11 is a flowchart of a fail recovery method according to an exemplary embodiment of the disclosure.

FIG. 12 is a flowchart of a fail recovery method according to an exemplary embodiment of the disclosure.

### DESCRIPTION OF THE EMBODIMENTS

Generally speaking, a memory storage device (also referred to as a memory storage system) includes a rewritable non-volatile memory module and a controller (also referred to as a control circuit). The memory storage device may be used together with a host system for the host system to write data into the memory storage device or read data from the memory storage device.

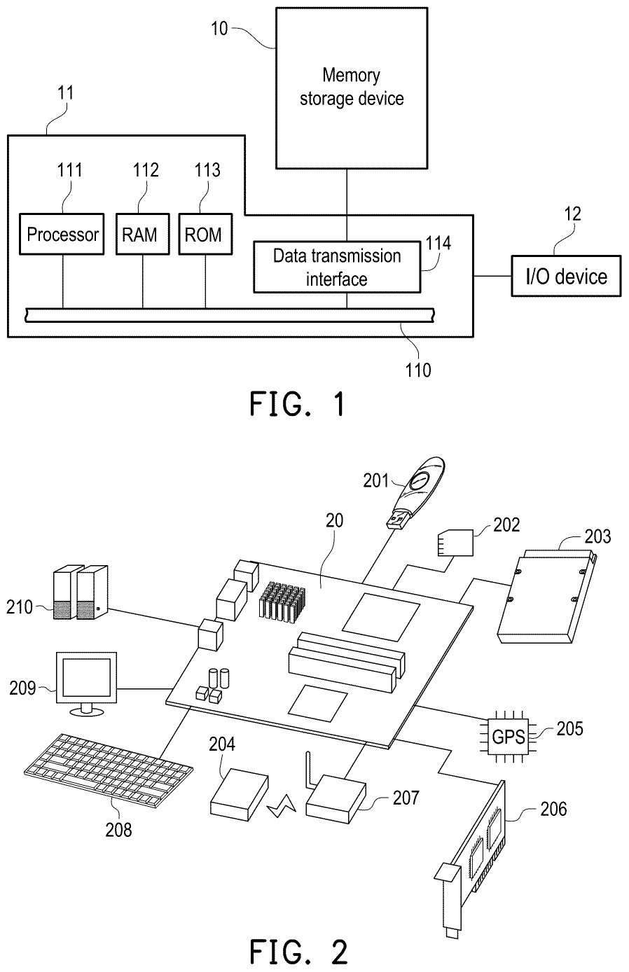

FIG. 1 is a schematic diagram showing a host system, a memory storage device, and an input/output (I/O) device according to an exemplary embodiment of the disclosure. FIG. 2 is a schematic diagram showing a host system, a memory storage device, and an I/O device according to an exemplary embodiment of the disclosure.

Referring to FIG. 1 and FIG. 2, a host system 11 may include a processor 111, a random access memory (RAM) 112, a read only memory (ROM) 113, and a data transmission interface 114. The processor 111, the random access memory 112, the read only memory 113, and the data transmission interface 114 may be coupled to a system bus 110.

In an exemplary embodiment, the host system 11 may be coupled to a memory storage device 10 through the data transmission interface 114. For example, the host system 11 may store data into the memory storage device 10 or read data from the memory storage device 10 through the data transmission interface 114. In addition, the host system 11 may be coupled to an I/O device 12 through the system bus 110. For example, the host system 11 may transmit an output signal to the I/O device 12 or receive an input signal from the I/O device 12 through the system bus 110.

In an exemplary embodiment, the processor 111, the random access memory 112, the read only memory 113, and the data transmission interface 114 may be disposed on a motherboard 20 of the host system 11. The data transmission interface 114 may include one or more data transmission interfaces. Through the data transmission interface 114, the motherboard 20 may be coupled to the memory storage device 10 in a wired or wireless manner.

In an exemplary embodiment, the memory storage device 10 may be, for example, a flash drive 201, a memory card 202, a solid state drive (SSD) 203, or a wireless memory storage device 204. The wireless memory storage device 204 may be, for example, a near-field communication (NFC) memory storage device, a Wireless Fidelity (WiFi) memory storage device, a Bluetooth memory storage device, a Bluetooth Low Energy memory storage device (e.g., iBeacon), or any other memory storage device based on various modes of wireless communication technology. In addition, the motherboard 20 may also be coupled to various I/O devices such as a Global Positioning System (GPS) module 205, a network interface card 206, a wireless transmission device 207, a keyboard 208, a screen 209, or a speaker 210 through the system bus 110. For example, in an exemplary embodiment, the motherboard 20 may access the wireless memory storage device 204 through the wireless transmission device 207.

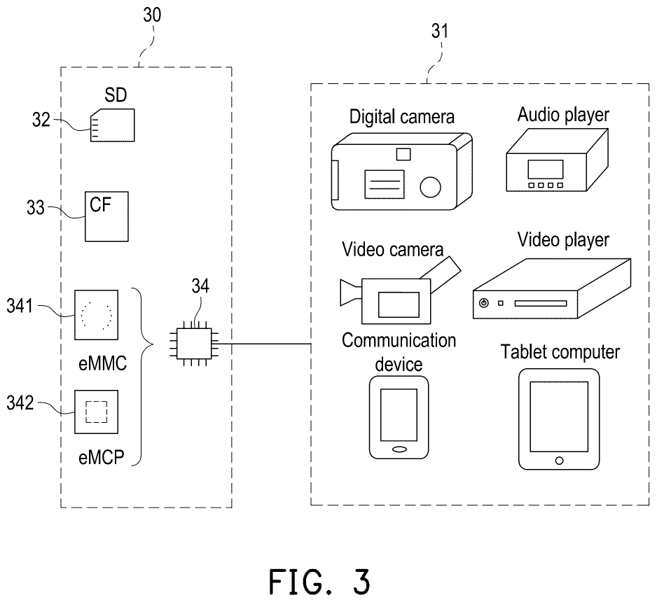

In an exemplary embodiment, the host system 11 is a computer system. In an exemplary embodiment, the host system 11 may be any system that substantially works with a memory storage device to store data. In an exemplary embodiment, the memory storage device 10 and the host system 11 may respectively include a memory storage device 30 and a host system 31 in FIG. 3.

FIG. 3 is a schematic diagram showing a host system and a memory storage device according to an exemplary embodiment of the disclosure. Referring to FIG. 3, the memory storage device 30 may be used with the host system 31 to store data. For example, the host system 31 may be a system such as a digital camera, a video camera, a communication device, an audio player, a video player, or a tablet computer. For example, the memory storage device 30 may be various non-volatile memory storage devices such as a Secure Digital (SD) card 32, a Compact Flash (CF) card 33, or an embedded storage device 34 used by the host system 31. The embedded storage device 34 includes embedded storage devices in various forms, such as an embedded Multi Media Card (eMMC) 341 and/or an embedded Multi Chip Package (eMCP) storage device 342, which directly couple the memory module to the substrate of the host system.

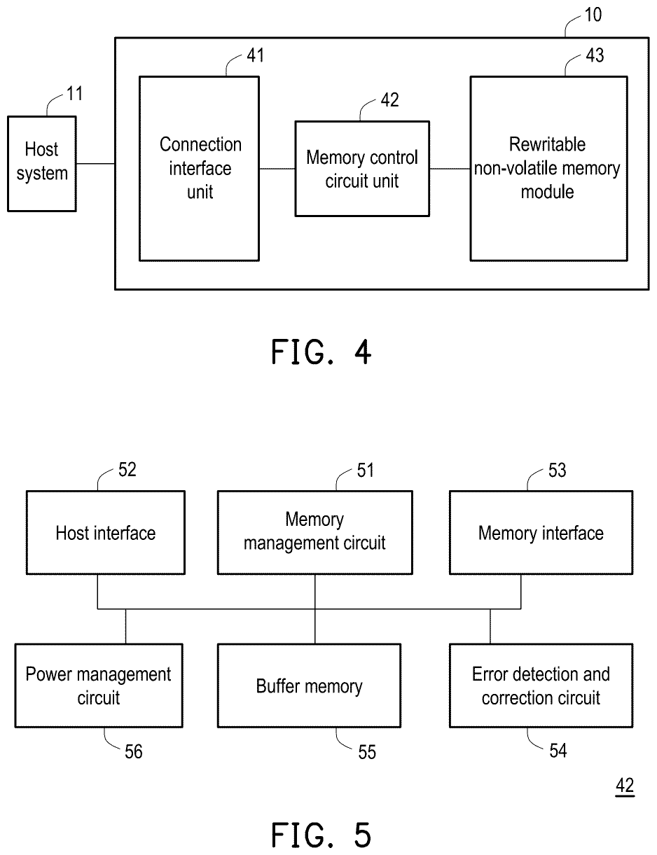

FIG. 4 is a schematic diagram showing a memory storage device according to an exemplary embodiment of the disclosure. Referring to FIG. 4, the memory storage device 10 includes a connection interface unit 41, a memory control circuit unit 42, and a rewritable non-volatile memory module 43.

The connection interface unit 41 is configured to be coupled to the host system 11. The memory storage device 10 may communicate with the host system 11 through the connection interface unit 41. In an exemplary embodiment, the connection interface unit 41 is compatible with Peripheral Component Interconnect Express (PCI Express). In an exemplary embodiment, the connection interface unit 41 may also be compatible with the Serial Advanced Technology Attachment (SATA) standard, Parallel Advanced Technology Attachment (PATA) standard, Institute of Electrical and Electronic Engineers (IEEE) 1394 standard, Universal Serial Bus (USB) Standard, SD interface standard, Ultra High Speed-I (UHS-I) interface standard, Ultra High Speed-II (UHS-II) interface standard, Memory Stick (MS) interface standard, MCP interface standard, MMC interface standard, eMMC Interface standard, Universal Flash Storage (UFS) interface standard, eMCP interface standard, CF interface standard, Integrated Device Electronics (IDE) standard, or other suitable standards. The connection interface unit 41 may be packaged into the same chip with the memory control circuit unit 42. Alternatively, the connection interface unit 41 may be arranged outside a chip including the memory control circuit unit 42.

The memory control circuit unit 42 is coupled to the connection interface unit 41 and the rewritable non-volatile memory module 43. The memory control circuit unit 42 is configured to execute a plurality of logic gates or control instructions implemented in a hardware form or firmware form and performs operations such as writing, reading, and erasing data in the rewritable non-volatile memory module 43 according to instructions of the host system 11.

The rewritable non-volatile memory module 43 is configured to store data written by the host system 11. The rewritable non-volatile memory module 43 may include a single-level cell (SLC) NAND-type flash memory module (i.e., a flash memory module that stores 1 bit in one memory cell), a multi-level cell (MLC) NAND-type flash memory module (i.e., a flash memory module that stores 2 bits in one memory cell), a triple-level cell (TLC) NAND-type flash memory module (i.e., a flash memory module that stores 3 bits in one memory cell), a quad-level cell (QLC) NAND-type flash memory module (i.e., a flash memory module that stores 4 bits in one memory cell), other flash memory modules, or other memory modules with the same properties.

In the rewritable non-volatile memory module 43, each memory cell stores one or more bits by a voltage change (hereinafter also referred to as a threshold voltage). Specifically, in each memory cell, an electric charge trapping layer is present between a control gate and a channel. By applying a write voltage to the control gate, the amount of electrons in the electric charge trapping layer may be changed, further changing the threshold voltage of the memory cell. This operation of changing the threshold voltage of the memory cell is also referred to as “writing data into the memory cell” or “programming the memory cell”. As the threshold voltage changes, each memory cell in the rewritable non-volatile memory module 43 may be in a plurality of storage states. By applying a read voltage, the storage state to which a memory cell belongs may be determined, thereby obtaining one or more bits stored in the memory cell.

In an exemplary embodiment, the memory cells of the rewritable non-volatile memory module 43 may constitute a plurality of physical programming units, and the physical programming units may constitute a plurality of physical erasing units. Specifically, the memory cells on the same word line may form one or more physical programming units. If each memory cell stores more than 2 bits, the physical programming units on the same word line may be at least classified into a lower physical programming unit and an upper physical programming unit. For example, the least significant bit (LSB) of a memory cell belongs to the lower physical programming unit, and the most significant bit (MSB) of a memory cell belongs to the upper physical programming unit. Generally speaking, in MLC NAND-type flash memory, the write speed of the lower physical programming unit is greater than the write speed of the upper physical programming unit, and/or the reliability of the lower physical programming unit is higher than the reliability of the upper physical programming unit.

In an exemplary embodiment, the physical programming units are the minimum unit for programming. That is, the physical programming units are the minimum unit for data write. For example, the physical programming units may include a physical page or a physical sector. If the physical programming units are physical pages, the physical programming units may include a data bit region and a redundancy bit region. The data bit region includes a plurality of physical sectors configured to store user data, and the redundancy bit region is configured to store system data (e.g., error correcting codes or other management data). In an exemplary embodiment, the data bit region includes 32 physical sectors, and the size of a physical sector is 512 bytes (B). However, in other exemplary embodiments, the data bit region may also include 8, 16, or more or less physical sectors, and the size of each physical sector may also be greater or smaller. On the other hand, the physical erasing units are the minimum unit of erase. That is, each physical erasing unit includes the minimum number of memory cells that are erased together. For example, the physical erasing units include a physical block.

FIG. 5 is a schematic diagram showing a memory control circuit unit according to an exemplary embodiment of the disclosure. Referring to FIG. 5, the memory control circuit unit 42 includes a memory management circuit 51, a host interface 52, and a memory interface 53.

The memory management circuit 51 is configured to control the overall operation of the memory control circuit unit 42. Specifically, there exist a plurality of control instructions in the memory management circuit 51. During operation of the memory storage device 10, the control instructions are executed to perform operations such as writing, reading, and erasing data. Hereinafter, when the operation of the memory management circuit 51 is described, the operation of the memory control circuit unit 42 is equivalently described.

In an exemplary embodiment, the control instructions of the memory management circuit 51 are implemented in a firmware form. For example, the memory management circuit 51 is provided with a microprocessor unit (not shown) and read only memory (not shown), and the control instructions are programmed into the read only memory. During operation of the memory storage device 10, the control instructions are executed by the microprocessor unit to perform operations such as writing, reading, and erasing data.

In an exemplary embodiment, the control instructions of the memory management circuit 51 may also be stored in a specific area (e.g., a system region dedicated to storing system data in the memory module) of the rewritable non-volatile memory module 43 in the form of a programming code. In addition, the memory management circuit 51 is provided with a microprocessor unit (not shown), read only memory (not shown), and random access memory (not shown). In particular, there exists a boot code in the read only memory. When the memory control circuit unit 42 is enabled, the microprocessor unit first executes the boot code to load the control instructions stored in the rewritable non-volatile memory module 43 into the random access memory of the memory management circuit 51. After that, the microprocessor unit operates the control instructions to perform operations such as writing, reading, and erasing data.

In an exemplary embodiment, the control instructions of the memory management circuit 51 may also be implemented in a hardware form. For example, the memory management circuit 51 includes a microcontroller, a memory cell management circuit, a memory write circuit, a memory read circuit, a memory erase circuit, and a data processing circuit. The memory cell management circuit, the memory write circuit, the memory read circuit, the memory erase circuit, and the data processing circuit are coupled to the microcontroller. The memory cell management circuit is configured to manage a memory cell or a memory cell group of the rewritable non-volatile memory module 43. The memory write circuit is configured to issue a write command sequence to the rewritable non-volatile memory module 43 to write data into the rewritable non-volatile memory module 43. The memory read circuit is configured to issue a read instruction sequence to the rewritable non-volatile memory module 43 to read data from the rewritable non-volatile memory module 43. The memory erase circuit is configured to issue an erase instruction sequence to the rewritable non-volatile memory module 43 to erase data from the rewritable non-volatile memory module 43. The data processing circuit is configured to process data to be written to the rewritable non-volatile memory module 43 and data read from the rewritable non-volatile memory module 43. The write command sequence, the read instruction sequence, and the erase instruction sequence may each include one or more programming codes or instruction codes and are configured to instruct the rewritable non-volatile memory module 43 to perform corresponding write, read, and erase operations among other operations. In an exemplary embodiment, the memory management circuit 51 may also issue other types of instruction sequences to the rewritable non-volatile memory module 43 to instruct the rewritable non-volatile memory module 43 to perform corresponding operations.

The host interface 52 is coupled to the memory management circuit 51. The memory management circuit 51 may communicate with the host system 11 through the host interface 52. The host interface 52 may be configured to receive and identify instructions and data transmitted by the host system 11. For example, the instructions and data transmitted by the host system 11 may be transmitted to the memory management circuit 51 through the host interface 52. In addition, the memory management circuit 51 may transmit data to the host system 11 through the host interface 52. In this exemplary embodiment, the host interface 52 is compatible with the PCI Express standard. However, it should be understood that the disclosure is not limited thereto. The host interface 52 may also be compatible with the SATA standard, PATA standard, IEEE 1394 standard, USB standard, SD standard, UHS-I standard, UHS-II standard, MS standard, MMC standard, eMMC standard, UFS standard, CF standard, IDE standard or other suitable data transmission standard.

The memory interface 53 is coupled to the memory management circuit 51 and configured to access the rewritable non-volatile memory module 43. For example, the memory management circuit 51 may access the rewritable non-volatile memory module 43 through the memory interface 53. In other words, data to be written into the rewritable non-volatile memory module 43 is converted through the memory interface 53 into a format acceptable by the rewritable non-volatile memory module 43. Specifically, when the memory management circuit 51 is to access the rewritable non-volatile memory module 43, the memory interface 53 will transmit corresponding instruction sequences. For example, the instruction sequences may include a write command sequence commanding data be written, a read instruction sequence commanding data be read, an erase instruction sequence indicating data be erased, and corresponding instruction sequences commanding various memory operations (e.g., changing the read voltage level or performing a garbage collection operation, etc.). The instruction sequences are, for example, generated by the memory management circuit 51 and transmitted through the memory interface 53 to the rewritable non-volatile memory module 43. The instruction sequences may include one or more signals, or data on a bus. The signals or data may include instruction codes or programming codes. For example, in the read instruction sequence, information such as a read identification code or a memory address is included.

In an exemplary embodiment, the memory control circuit unit 42 further includes an error detection and correction circuit 54, a buffer memory 55, and a power management circuit 56.

The error detection and correction circuit 54 is coupled to the memory management circuit 51 and configured to perform error detection and correction operations to ensure data correctness. Specifically, when the memory management circuit 51 receives a write command from the host system 11, the error detection and correction circuit 54 generates a corresponding error correcting code (ECC) and/or error detecting code (EDC) for data corresponding to the write command. In addition, the memory management circuit 51 writes the data corresponding to the write command and the corresponding error correcting code and/or error detecting code into the rewritable non-volatile memory module 43. Later, while reading data from the rewritable non-volatile memory module 43, the memory management circuit 51 also reads the error correcting code and/or error detecting code corresponding to the data. Moreover, the error detection and correction circuit 54 performs error detection and correction operations on the read data according to the error correcting code and/or error detecting code.

The buffer memory 55 is coupled to the memory management circuit 51 and configured to temporarily store data. The power management circuit 56 is coupled to the memory management circuit 51 and configured to control the power of the memory storage device 10.

In an exemplary embodiment, the rewritable non-volatile memory module 43 in FIG. 4 may include a flash memory module. In an exemplary embodiment, the memory control circuit unit 42 may include a flash memory controller. In an exemplary embodiment, the memory management circuit 51 in FIG. 5 may include a flash memory management circuit.

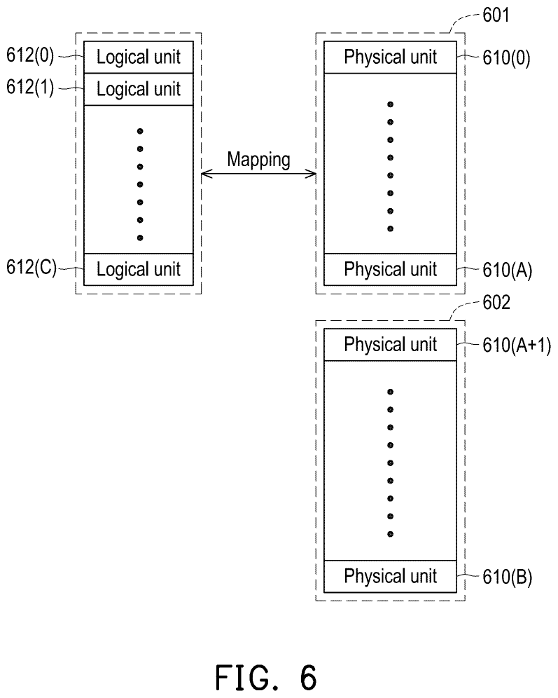

FIG. 6 is a schematic diagram showing management of a rewritable non-volatile memory module according to an exemplary embodiment of the disclosure. Referring to FIG. 6, the memory management circuit 51 may logically group physical units 610(0) to 610(B) in the rewritable non-volatile memory module 43 into a storage region 601 and a spare region 602.

In an exemplary embodiment, a physical unit refers to a physical address or a physical programming unit. In an exemplary embodiment, a physical unit may also be composed of a plurality of continuous or discontinuous physical addresses. In an exemplary embodiment, a physical unit may also refer to a virtual block (VB). A virtual block may include a plurality of physical addresses or a plurality of physical programming units. In an exemplary embodiment, a virtual block may include one or more physical erase units.

The physical units 610(0) to 610(A) in the storage region 601 are configured to store user data (e.g., user data from the host system 11 in FIG. 1). For example, the physical units 610(0) to 610(A) in the storage region 601 may store valid data and invalid data. The physical units 610(A+1) to 610 (B) in the spare region 602 do not store data (e.g., valid data). For example, if a certain physical unit does not store valid data, this physical unit may be associated with (or added to) the spare region 602. In addition, the physical unit in the spare region 602 (or the physical unit that does not store valid data) may be erased. When new data is written, one or more physical units may be retrieved from the spare region 602 to store the new data. In an exemplary embodiment, the spare region 602 is also referred to as a free pool.

The memory management circuit 51 may be provided with logical units 612(0) to 612(C) to be mapped to the physical units 610(0) to 610(A) in the storage region 601. In an exemplary embodiment, each logical unit corresponds to one logical address. For example, one logical address may include one or more logical block addresses (LBA) or other logical management units. In an exemplary embodiment, one logical unit may also correspond to one logical programming unit or may be formed by a plurality of continuous or discontinuous logical addresses.

Note that one logical unit may be mapped to one or more physical units. If a certain physical unit is currently mapped to a certain logical unit, it means that data currently stored in this physical unit includes valid data. Comparatively, if a certain physical unit is currently not mapped to any logical unit, it means that data currently stored in this physical unit is invalid data.

The memory management circuit 51 may record management data (also referred to as logical-to-physical mapping information) describing a mapping relationship between the logical unit and the physical unit in at least one logical-to-physical mapping table. When the host system 11 intends to read data from the memory storage device 10 or write data into the memory storage device 10, the memory management circuit 51 may access the rewritable non-volatile memory module 43 according to the information in the logical-to-physical mapping table.

In an exemplary embodiment, when a write, read, or erase operation for a certain physical unit fails, the memory management circuit 51 may record the physical address of this physical unit and the error type in at least one bad block table. Afterward, the physical units recorded in the bad block table will no longer be used to access data. In an exemplary embodiment, when an erase operation corresponding to a certain physical unit fails (i.e., an error occurs), the memory management circuit 51 may record the physical address of this physical unit and the error type (e.g., Erase Status Fail (ESF)) in the bad block table. In an exemplary embodiment, when a write operation corresponding to a certain physical unit fails, the memory management circuit 51 may record the physical address of this physical unit and the error type (e.g., Program Status Fail (PSF)) in the bad block table. In an exemplary embodiment, when a read operation corresponding to a certain physical unit fails, the memory management circuit 51 may record the physical address of this physical unit and the error type (e.g., Uncorrectable Error Correction Code (UECC)) in the bad block table.

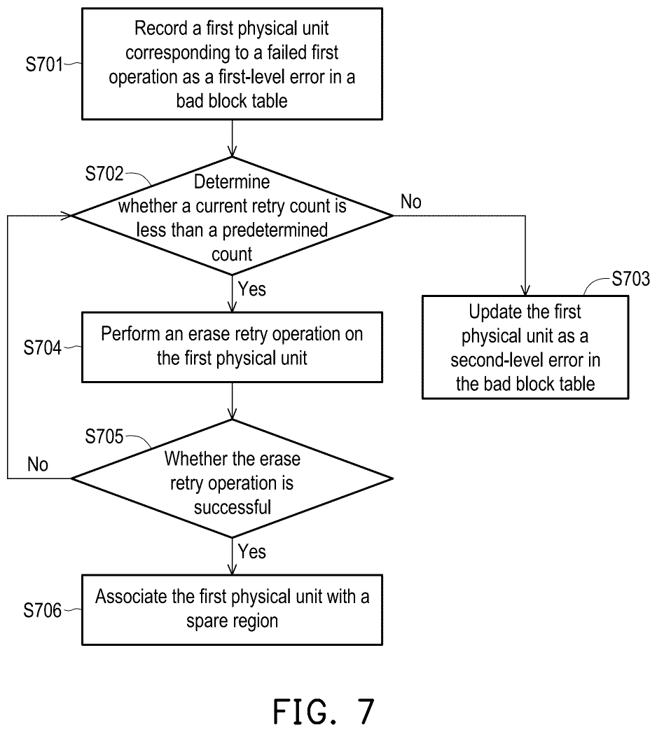

FIG. 7 is a flowchart of a fail recovery method according to an exemplary embodiment of the disclosure. Referring to FIG. 7, in step S701, the memory management circuit 51 may record a first physical unit corresponding to a failed first operation as a first-level error in a bad block table. The first operation may be, for example, an erase operation, a write operation, or a read operation. In an exemplary embodiment, the error types in the bad block table may be divided into first-level errors and second-level errors. For example, a first-level error is configured to indicate that a certain physical unit is a bad physical unit that has experienced a write operation error, an erase operation error, or a read operation error. In other words, a first-level error may be PSF, ESF, or UECC. For example, a second-level error is configured to indicate that a certain physical unit is a bad physical unit that has been determined through the fail recovery method provided by this disclosure to be no longer usable for accessing data. Specifically, the exemplary embodiment of this disclosure provides an error type classification mechanism. The memory management circuit 51 may record a certain physical unit where an error has occurred as a first-level error in the bad block table, and then execute the fail recovery method of this disclosure for this physical unit to determine whether this physical unit may continue to be used for accessing data in actual usage scenarios, thereby improving the access performance of the rewritable non-volatile memory module 43. In an exemplary embodiment, the memory management circuit 51 may record a first physical unit that has experienced an erase failure as a first-level error (i.e., ESF) in the bad block table.

In step S702, the memory management circuit 51 may determine whether the current retry count is less than a predetermined count. Specifically, the fail recovery method shown in FIG. 7 may determine whether the first physical unit may continue to be used for accessing data in actual usage scenarios by performing an erase retry operation on the first physical unit up to a predetermined count (e.g., 3 times). The predetermined count may be, for example, designed by the user according to actual requirements, which is not limited by the disclosure.

In an exemplary embodiment, the current retry count is used to represent a number of times an erase retry operation is performed on the first physical unit. If the current retry count is not less than the predetermined count, meaning the current retry count has reached 3 times, the process enters step S703, where the memory management circuit 51 may update the first physical unit as a second-level error in the bad block table. Specifically, if all the predetermined count of erase retry operations performed by the memory management circuit 51 on the first physical unit have failed, the memory management circuit 51 may determine that the first physical unit may no longer be used for accessing data in actual usage scenarios. Accordingly, the memory management circuit 51 may update the first physical unit from a first-level error to a second-level error in the bad block table.

On the other hand, if the current retry count (e.g., 0 times) is less than the predetermined count (i.e., 3 times), the process enters step S704. In step S704, the memory management circuit 51 may perform an erase retry operation on the first physical unit. Afterward, in step S705, the memory management circuit 51 may determine whether the erase retry operation is successful.

If the erase retry operation is successful, the process enters step S706, where the memory management circuit 51 may associate the first physical unit with the spare region 602. Specifically, a successful erase retry operation indicates that the first physical unit may continue to be used for accessing data in actual usage scenarios. Therefore, the memory management circuit 51 may remove the successfully erased first physical unit from the bad block table and associate the first physical unit with the spare region 602.

Conversely, if the erase retry operation fails, the process returns to step S702 to determine again whether the current retry count is less than the predetermined count. At this point, the current retry count is 1, so the memory management circuit 51 may proceed with steps S704 and S705 to perform another erase retry operation on the first physical unit and determine whether this erase retry operation is successful. If this erase retry operation is successful, the process enters step S706. On the contrary, if this erase retry operation fails, the process returns to step S702 again. At this time, the current retry count is 2, and the memory management circuit 51 may perform steps S704 and S705 again, and either enter step S706 to associate the first physical unit with the spare region 602 based on the success of the erase retry operation, or return to step S702 based on the failure of the erase retry operation. At this point, the current retry count is 3, so the process may enter step S703 to update the first physical unit as a second-level error in the bad block table.

According to the above, the fail recovery method shown in FIG. 7 may perform an erase retry operation on the physical unit that failed to erase, and in response to the successful erase retry operation, re-associate this physical unit with the spare region 602, allowing this physical unit to continue to be used for accessing data, thereby improving the access performance of the rewritable non-volatile memory module 43.

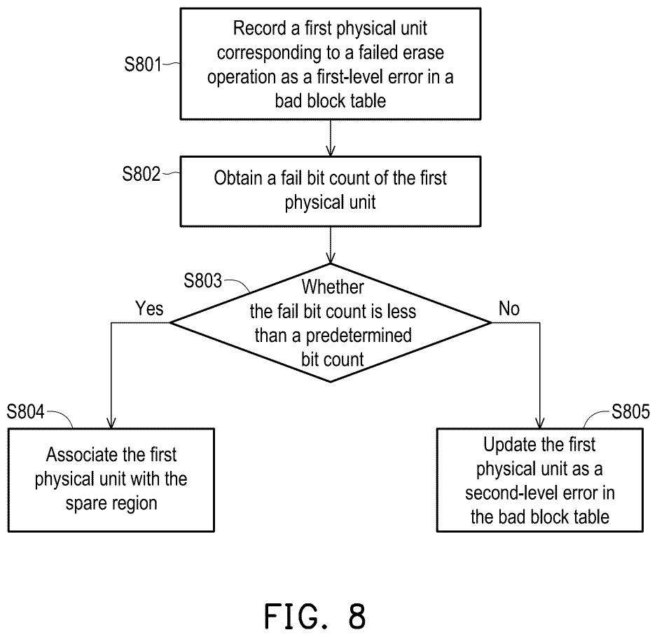

FIG. 8 is a flowchart of a fail recovery method according to an exemplary embodiment of the disclosure. Referring to FIG. 8, in step S801, the memory management circuit 51 may record the first physical unit corresponding to the failed erase operation as a first-level error in the bad block table. For implementation details of step S801, reference may be made to the aforementioned step S701, which will not be repeated here.

In step S802, the memory management circuit 51 may obtain the fail bit count (FBC) of the first physical unit. In an exemplary embodiment, the memory management circuit 51 may, for example, obtain the fail bit count of the first physical unit based on a threshold voltage (VT). For instance, the memory management circuit 51 may issue a threshold voltage distribution (VT distribution) command to the first physical unit to read data from the first physical unit, and detect the fail bit count of the first physical unit according to this data. Specifically, if a certain physical unit has severe physical wear (e.g., significant charge loss), this physical unit has a higher fail bit count and is not suitable for continued use in accessing data.

In step S803, the memory management circuit 51 may determine whether the fail bit count is less than a predetermined bit count. Specifically, the fail recovery method shown in FIG. 8 may determine whether the first physical unit may continue to be used for accessing data in actual use scenarios through the fail bit count of the first physical unit. The predetermined bit count may be, for example, designed by the user according to actual requirements, or may be related to the bit count contained in a physical programming unit, which is not limited by the disclosure.

If the fail bit count is less than the predetermined bit count, it indicates that the first physical unit may continue to be used for accessing data in actual use scenarios, and the process enters step S804. In step S804, the memory management circuit 51 may associate the first physical unit with the spare region 602.

On the other hand, if the fail bit count is not less than the predetermined bit count, it indicates that the first physical unit may not continue to be used for accessing data in actual use scenarios, and the process enters step S805. In step S805, the memory management circuit 51 may update the first physical unit as a second-level error in the bad block table.

According to the above, the fail recovery method shown in FIG. 8 may obtain the fail bit count of the physical unit that failed to erase, and in response to the fail bit count being less than the predetermined bit count, re-associate this physical unit with the spare region 602, allowing this physical unit to continue to be used for accessing data, thereby improving the access performance of the rewritable non-volatile memory module 43.

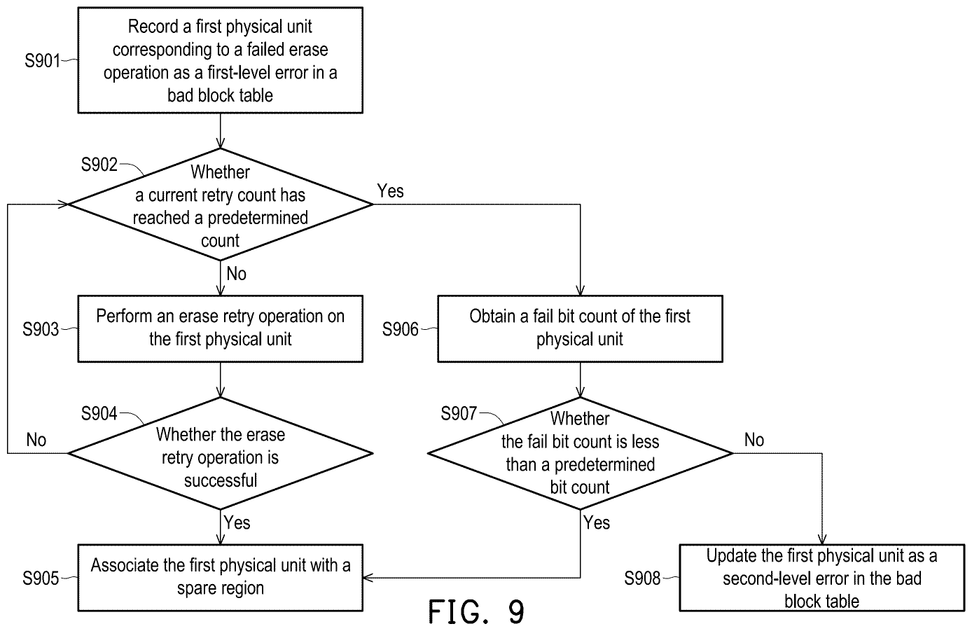

FIG. 9 is a flowchart of a fail recovery method according to an exemplary embodiment of the disclosure. It should be noted that the fail recovery method shown in FIG. 9 is a combination of the fail recovery methods shown in FIG. 7 and FIG. 8, which may more accurately determine whether the physical unit experiencing an erase error may continue to be used for accessing data.

Referring to FIG. 9, in step S901, the memory management circuit 51 may record the first physical unit corresponding to the failed erase operation (also referred to as the first operation) as a first-level error in the bad block table. For implementation details of step S901, reference may be made to the aforementioned step S701, which will not be repeated here.

In step S902, the memory management circuit 51 may determine whether the current retry count has reached a predetermined count. Specifically, the fail recovery method shown in FIG. 9 may perform erase retry operations on the first physical unit up to a predetermined count (e.g., 3 times), and after performing the predetermined count of erase retry operations, further detect the fail bit count of the first physical unit to determine whether the first physical unit may continue to be used for accessing data in actual use scenarios. The predetermined count may be, for example, designed by the user according to actual requirements, which is not limited by the disclosure.

If the current retry count reaches the predetermined count, the process enters step S906.

On the other hand, if the current retry count (e.g., 0 times) has not reached the predetermined count, meaning the current retry count is less than 3 times, the process enters step S903, where the memory management circuit 51 may perform an erase retry operation on the first physical unit. Afterward, in step S904, the memory management circuit 51 may determine whether the erase retry operation is successful. If the erase retry operation is successful (meaning the first physical unit may continue to be used for accessing data in actual use scenarios), then the process enters step S905, where the memory management circuit 51 may associate the first physical unit with the spare region 602.

Conversely, if the erase retry operation fails, the process returns to step S902. At this point, the current retry count is 1, so the memory management circuit 51 may proceed with steps S903 and S904 to perform another erase retry operation on the first physical unit and determine whether this erase retry operation is successful. If this erase retry operation is successful, the process enters step S905. On the contrary, if this erase retry operation fails, the process returns to step S902 again. At this point, the current retry count is 2, and the memory management circuit 51 may again perform steps S903 and S904, and either enter step S905 to associate the first physical unit with the spare region 602 based on the success of the erase retry operation, or return to step S902 based on the failure of the erase retry operation. At this point, the current retry count is 3, meaning the current retry count has reached the predetermined count, and the process enters step S906.

In step S906, the memory management circuit 51 may obtain the fail bit count of the first physical unit. For example, the memory management circuit 51 may obtain the fail bit count of the first physical unit based on the threshold voltage. For instance, the memory management circuit 51 may issue a VT distribution command to the first physical unit to read data from the first physical unit, and detect the fail bit count of the first physical unit according to this data.

Afterward, in step S907, the memory management circuit 51 may determine whether the fail bit count is less than a predetermined bit count. If the fail bit count is less than the predetermined bit count, it indicates that the first physical unit may continue to be used for accessing data in actual use scenarios, and the process enters step S905, where the memory management circuit 51 may associate the first physical unit with the spare region 602. Conversely, if the fail bit count is not less than the predetermined bit count, it indicates that the first physical unit may not continue to be used for accessing data in actual use scenarios, and the process enters step S908, where the memory management circuit 51 may update the first physical unit as a second-level error in the bad block table.

According to the above, the fail recovery method shown in FIG. 9 may perform an erase retry operation (and obtain the fail bit count of the physical unit that failed to erase) for the physical unit that failed to erase, and in response to the success of the erase retry operation (or the fail bit count being less than the predetermined bit count), re-associate this physical unit with the spare region 602, allowing this physical unit to continue to be used for accessing data, thereby improving the access performance of the rewritable non-volatile memory module 43.

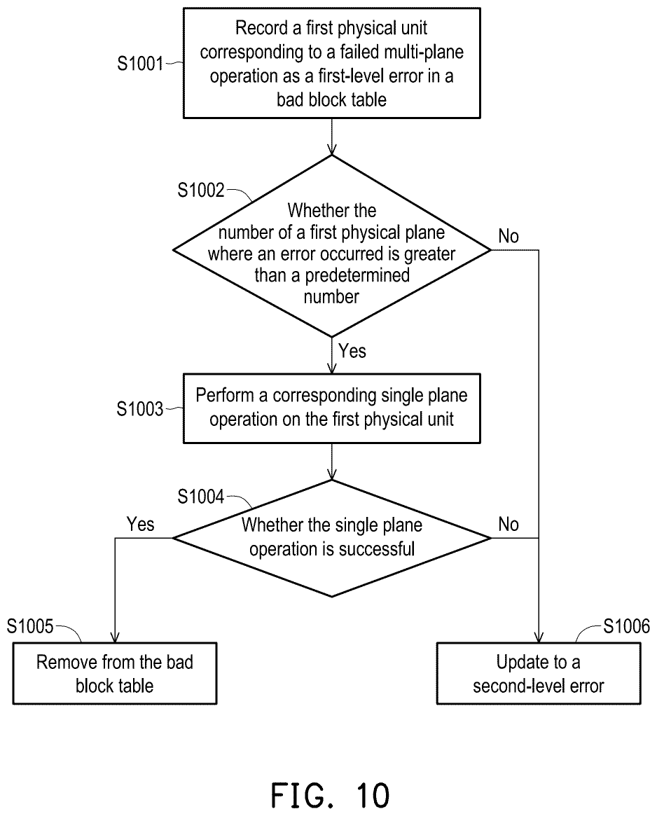

FIG. 10 is a flowchart of a fail recovery method according to an exemplary embodiment of the disclosure. In an exemplary embodiment, the rewritable non-volatile memory module 43 may, for example, include a plurality of physical planes (not shown), with each physical plane including a plurality of physical units. Generally, operations such as writing, erasing, or reading executed by the memory management circuit 51 are typically multi-plane operations. For example, assuming the rewritable non-volatile memory module 43 has 4 physical planes, the memory management circuit may perform multi-plane operations to simultaneously perform operations such as writing, erasing, or reading on physical planes in these 4 physical planes.

It should be noted that these 4 physical planes may interfere with each other. For example, when an error occurs in one physical plane (a physical unit belonging to a certain physical plane), another adjacent physical plane (a physical unit belonging to another physical plane) may be affected by leakage current from this physical plane and experience an error. In some cases, the physical unit that experiences an error due to the influence of leakage current may continue to be used for accessing data in actual use scenarios. Therefore, the exemplary embodiment of this disclosure provides the fail recovery method of FIG. 10, which may further analyze the physical planes that may continue to be used for accessing data, thereby improving the access performance of the rewritable non-volatile memory module 43.

Referring to FIG. 10, in step S1001, the memory management circuit 51 may record the first physical unit corresponding to the failed multi-plane operation as a first-level error in the bad block table. Specifically, the memory management circuit 51 may record the first physical unit corresponding to the multi-plane operation in the physical plane where the error occurred (also called the first physical plane) as a first-level error. In an exemplary embodiment, the multi-plane operation may include, but is not limited to, write, erase, or read operations executed simultaneously on all physical planes in the rewritable non-volatile memory module 43.

In step S1002, the memory management circuit 51 may determine if the number of the first physical plane where an error occurred is greater than a predetermined number (e.g., 1). If the number of the first physical plane where the error occurred is not greater than the predetermined number, meaning only one physical plane in the rewritable non-volatile memory module 43 experienced an error, then the process proceeds to step S1006. In step S1006, the memory management circuit 51 may update the first physical unit belonging to the first physical plane as a second-level error in the bad block table. Specifically, since only one physical plane experienced an error, the first physical unit corresponding to the failed multi-plane operation was not affected by leakage current, so the memory management circuit 51 may, for example, determine that the first physical unit has physical wear and may not continue to be used for accessing data. Therefore, the memory management circuit 51 may update the first physical unit as a second-level error in the bad block table.

Conversely, if the number of the first physical plane where the error occurred (e.g., 2) is greater than the predetermined number, meaning a plurality of physical planes in the rewritable non-volatile memory module 43 experienced errors, then the process proceeds to step S1003. The predetermined number may be, for example, designed by the user according to actual requirements, which is not limited by the disclosure.

In step S1003, the memory management circuit 51 may perform a corresponding single plane operation on the first physical unit. The memory management circuit 51 may perform single plane operations on the first physical units in the aforementioned 2 first physical planes respectively. In an exemplary embodiment, assuming the multi-plane operation is an erase operation, the memory management circuit 51 may perform single plane operations on the first physical units in a plurality of first physical planes, where the single plane operation is an erase retry operation. In an exemplary embodiment, assuming the multi-plane operation is a write operation or a read operation, the memory management circuit 51 may perform single plane operations on the first physical units in a plurality of first physical planes, where the single plane operation may be an executed erase retry operation, program retry operation, or read retry operation.

In step S1004, the memory management circuit 51 may determine whether the single plane operation is successful. If the single plane operation is successful, the process proceeds to step S1005. In an exemplary embodiment, if the single plane operation on the first physical unit is successful, it indicates that this first physical unit is affected by leakage current, so this first physical unit does not have physical wear and may continue to be used for accessing data. Therefore, in step S1005, the memory management circuit 51 may remove this first physical unit from the bad block table, thereby improving the access performance of the rewritable non-volatile memory module 43.

Conversely, if the single plane operation fails, the process proceeds to step S1006. In an exemplary embodiment, if the single plane operation on the first physical unit fails, it indicates that this first physical unit may have physical wear and may not continue to be used for accessing data. Therefore, in step S1006, the memory management circuit 51 may update this first physical unit in the bad block table from a first-level error to a second-level error.

According to the above, the fail recovery method shown in FIG. 10 may perform corresponding single plane operations on physical units in a plurality of physical planes where errors occurred, to determine whether the physical units may continue to be used for accessing data, thereby improving the access performance of the rewritable non-volatile memory module 43.

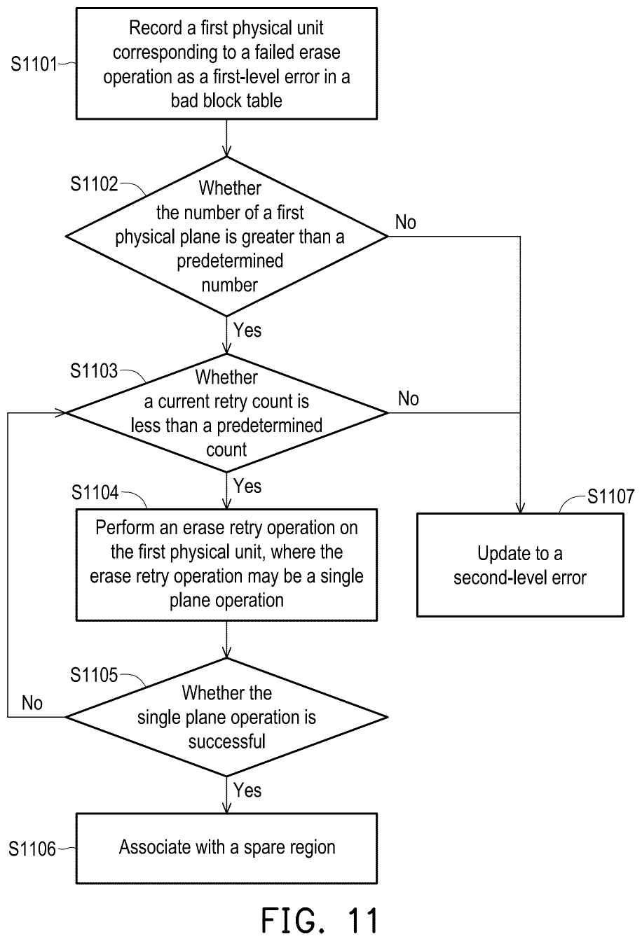

FIG. 11 is a flowchart of a fail recovery method according to an exemplary embodiment of the disclosure. It should be noted that the fail recovery method shown in FIG. 11 is a combination of the fail recovery methods shown in FIG. 7 and FIG. 10, which may more accurately determine whether the physical units corresponding to the failed erase multi-plane operation may continue to be used for accessing data.

Please refer to FIG. 11. In step S1101, the memory management circuit 51 may record the first physical unit corresponding to the failed erase operation (also referred to as the first operation) as a first-level error in the bad block table. In an exemplary embodiment, the erase operation may be a multi-plane operation. The memory management circuit 51 may record the first physical unit belonging to the physical plane where the erase error occurred (i.e., the first physical plane) as a first-level error in the bad block table.

In step S1102, the memory management circuit 51 may determine whether the number of the first physical plane is greater than a predetermined number (e.g., 1). If the number of the first physical plane is not greater than the predetermined number, meaning only one physical plane has an error, the process proceeds to step S1107. In step S1107, the memory management circuit 51 may update the first physical unit as a second-level error in the bad block table. Specifically, since only one physical plane has an error, the first physical unit is not affected by leakage current. In other words, the memory management circuit 51 may, for example, determine that the first physical unit has physical wear and may not continue to be used for accessing data. Therefore, the memory management circuit 51 may update the first physical unit from a first-level error to a second-level error in the bad block table.

Conversely, if the number of the first physical plane is greater than the predetermined number, meaning a plurality of physical planes have errors, the process then proceeds to step S1103. In step S1103, the memory management circuit 51 may determine whether the current retry count is less than a predetermined count (e.g., 2 times). Specifically, the memory management circuit 51 may determine whether the current retry count of the first physical unit in each of the plurality of first physical planes where errors occurred is less than the predetermined count. If the current retry count of a certain first physical unit is not less than the predetermined count, meaning the current retry count for this first physical unit has already reached 2, the memory management circuit 51 may determine that this first physical unit may not continue to be used for accessing data, and the process proceeds to step S1107. In step S1107, the memory management circuit 51 may update this first physical unit from a first-level error to a second-level error in the bad block table.

On the other hand, if the current retry count of a certain first physical unit (e.g., 0 times) is less than the predetermined count, the process proceeds to step S1104. In step S1104, the memory management circuit 51 may perform an erase retry operation on the first physical unit, where the erase retry operation may be a single plane operation. Afterward, in step S1105, the memory management circuit 51 may determine whether the single plane operation (i.e., the erase retry operation) is successful.

If the single plane operation (erase retry operation) is successful, the memory management circuit 51 may determine that this first physical unit may continue to be used for accessing data, and the process proceeds to step S1106, where the memory management circuit 51 may associate this first physical unit with the spare region 602.

Conversely, if the single plane operation (erase retry operation) fails, then the process returns to step S1103 to determine again whether the current retry count is less than the predetermined count. At this time, the current retry count is 1, so the memory management circuit 51 may proceed to steps S1104 and S1105 to perform the single plane operation (erase retry operation) on this first physical unit again, and determine whether this single plane operation (erase retry operation) is successful. If this single plane operation (erase retry operation) is successful, then the process proceeds to step S1106. On the contrary, if this single plane operation (erase retry operation) fails, then the process returns to step S1103 again. At this time, the current retry count is 2. Since the current retry count has reached 2 (i.e., the predetermined count), the process proceeds to step S1107 to update this first physical unit from a first-level error to a second-level error in the bad block table.

According to the above, the fail recovery method shown in FIG. 11 may perform single plane operations (erase retry operations) respectively on the physical units in a plurality of physical planes where erase operations have failed, and in response to the success of the single plane operation (erase retry operation), re-associate this physical unit with the spare region 602, allowing this physical unit to continue to be used for accessing data, thereby improving the access performance of the rewritable non-volatile memory module 43.

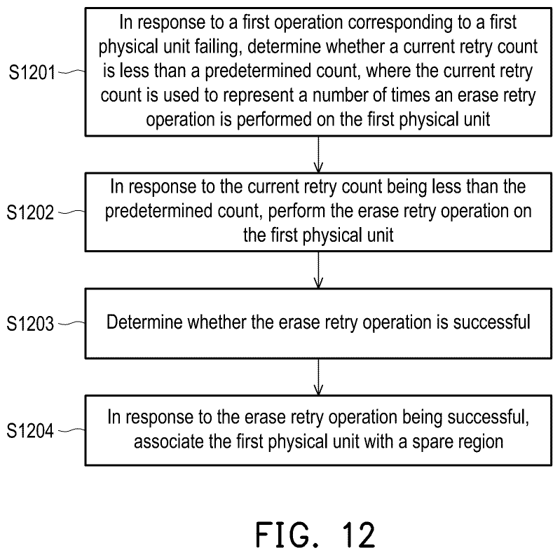

FIG. 12 is a flowchart of a fail recovery method according to an exemplary embodiment of the disclosure. Referring to FIG. 12, in step S1201, in response to a first operation corresponding to a first physical unit failing, determine whether the current retry count is less than a predetermined count, where the current retry count is used to represent a number of times an erase retry operation is performed on the first physical unit. In step S1202, in response to the current retry count being less than the predetermined count, an erase retry operation is performed on the first physical unit. In step S1203, it is determined whether the erase retry operation is successful. In step S1204, in response to the erase retry operation being successful, the first physical unit is associated with a spare region.

The steps in FIG. 12 have been explained in detail as above and so will not be repeated here. It is worth noting that each step in FIG. 12 may be implemented as a plurality of program codes or circuits, which is not limited by the disclosure. Moreover, the method of FIG. 12 may be used in conjunction with the above exemplary embodiments, or may be used independently, which is not limited by the disclosure.

In summary of the foregoing, the fail recovery method, the memory storage device, and the memory control circuit unit provided by the exemplary embodiment of the disclosure may, through the number of physical planes where errors occur, obtain the fail bit count of the physical unit and/or perform retry operations on the physical unit to further analyze whether the physical unit where an error occurred may continue to be used for accessing data, thereby improving the access performance of the rewritable non-volatile memory module while maintaining data correctness.

Although the disclosure has been described with reference to the embodiments above, the embodiments are not intended to limit the disclosure. Any person skilled in the art can make some changes and modifications without departing from the spirit and scope of the disclosure. Therefore, the scope of the disclosure will be defined in the appended claims.

What is claimed is:

1. A fail recovery method, configured for a rewritable non-volatile memory module, wherein the rewritable non-volatile memory module comprises a plurality of physical units, and the fail recovery method comprises:
in response to a first operation corresponding to a first physical unit failing, determining whether a current retry count is less than a predetermined count, wherein the current retry count is used to represent a number of times an erase retry operation is performed on the first physical unit;
in response to the current retry count being less than the predetermined count, performing the erase retry operation on the first physical unit;
determining whether the erase retry operation is successful; and
in response to the erase retry operation being successful, associating the first physical unit with a spare region.

2. The fail recovery method according to claim 1, further comprising:
in response to the erase retry operation failing, determining again whether the current retry count is less than the predetermined count.

3. The fail recovery method according to claim 1, further comprising:
in response to the current retry count reaching the predetermined count, obtaining a fail bit count of the first physical unit based on a threshold voltage;
determining whether the fail bit count is less than a predetermined bit count; and
in response to the fail bit count not being less than the predetermined bit count, updating the first physical unit as a second-level error in a bad block table.

4. The fail recovery method according to claim 3, further comprising:
in response to the fail bit count being less than the predetermined bit count, associating the first physical unit with the spare region again.

5. The fail recovery method according to claim 1, further comprising:
in response to the first operation being a multi-plane operation, determining whether the number of a first physical plane is greater than a predetermined number, wherein the first physical plane is a physical plane where an error occurs;
in response to the number being greater than the predetermined number, determining whether the current retry count is less than the predetermined count; and
in response to the current retry count being less than the predetermined count, performing the erase retry operation on the first physical unit belonging to the first physical plane, wherein the erase retry operation is a single plane operation.

6. The fail recovery method according to claim 5, further comprising:
in response to the number not being greater than the predetermined number, updating the first physical unit as a second-level error in a bad block table.

7. The fail recovery method according to claim 1, further comprising:
in response to the current retry count not being less than the predetermined count, updating the first physical unit as a second-level error in a bad block table.

8. The fail recovery method according to claim 1, further comprising:
in response to the first operation failing, recording the first physical unit as a first-level error in a bad block table.

9. A memory storage device, comprising:
a connection interface unit, coupled to a host system;
a rewritable non-volatile memory module, comprising a plurality of physical units; and
a memory control circuit unit, coupled to the connection interface unit and the rewritable non-volatile memory module,
wherein the memory control circuit unit is configured to:
in response to a first operation corresponding to a first physical unit failing, determine whether a current retry count is less than a predetermined count, wherein the current retry count is used to represent a number of times an erase retry operation is performed on the first physical unit;
in response to the current retry count being less than the predetermined count, perform the erase retry operation on the first physical unit;
determine whether the erase retry operation is successful; and
in response to the erase retry operation being successful, associate the first physical unit with a spare region.

10. The memory storage device according to claim 9, wherein the memory control circuit unit is further configured to:
in response to the erase retry operation failing, determine again whether the current retry count is less than the predetermined count.

11. The memory storage device according to claim 9, wherein the memory control circuit unit is further configured to:
in response to the current retry count reaching the predetermined count, obtain a fail bit count of the first physical unit based on a threshold voltage;
determine whether the fail bit count is less than a predetermined bit count; and
in response to the fail bit count not being less than the predetermined bit count, update the first physical unit as a second-level error in a bad block table.

12. The memory storage device according to claim 11, wherein the memory control circuit unit is further configured to:
in response to the fail bit count being less than the predetermined bit count, associate the first physical unit with the spare region.

13. The memory storage device according to claim 9, wherein the memory control circuit unit is further configured to:
in response to the first operation being a multi-plane operation, determine whether the number of a first physical plane is greater than a predetermined number, wherein the first physical plane is a physical plane where an error occurs;
in response to the number being greater than the predetermined number, determine whether the current retry count is less than the predetermined count; and
in response to the current retry count being less than the predetermined count, perform the erase retry operation on the first physical unit belonging to the first physical plane, wherein the erase retry operation is a single plane operation.

14. The memory storage device according to claim 13, wherein the memory control circuit unit is further configured to:
in response to the number not being greater than the predetermined number, update the first physical unit as a second-level error in a bad block table.

15. The memory storage device according to claim 9, wherein the memory control circuit unit is further configured to:
in response to the current retry count not being less than the predetermined count, update the first physical unit as a second-level error in a bad block table.

16. The memory storage device according to claim 9, wherein the memory control circuit unit is further configured to:
in response to the first operation failing, record the first physical unit as a first-level error in a bad block table.

17. A memory control circuit unit, configured for controlling a rewritable non-volatile memory module, wherein the rewritable non-volatile memory module comprises a plurality of physical units, and the memory control circuit unit comprises:
a host interface, coupled to a connection interface unit;
a memory interface, coupled to the rewritable non-volatile memory module; and
a memory management circuit, coupled to the host interface and the memory interface,
wherein the memory management circuit is configured to:
in response to a first operation corresponding to a first physical unit failing, determine whether a current retry count is less than a predetermined count, wherein the current retry count is used to represent a number of times an erase retry operation is performed on the first physical unit;
in response to the current retry count being less than the predetermined count, perform the erase retry operation on the first physical unit;
determine whether the erase retry operation is successful; and
in response to the erase retry operation being successful, associate the first physical unit with a spare region.

18. The memory control circuit unit according to claim 17, wherein the memory management circuit is further configured to:
in response to the erase retry operation failing, determine again whether the current retry count is less than the predetermined count.

19. The memory control circuit unit according to claim 17, wherein the memory management circuit is further configured to:
in response to the current retry count reaching the predetermined count, obtain a fail bit count of the first physical unit based on a threshold voltage;
determine whether the fail bit count is less than a predetermined bit count; and
in response to the fail bit count not being less than the predetermined bit count, update the first physical unit as a second-level error in a bad block table.

20. The memory control circuit unit according to claim 19, wherein the memory management circuit is further configured to:
in response to the fail bit count being less than the predetermined bit count, associate the first physical unit with the spare region.

21. The memory control circuit unit according to claim 17, wherein the memory management circuit is further configured to:
in response to the first operation being a multi-plane operation, determine whether the number of a first physical plane is greater than a predetermined number, wherein the first physical plane is a physical plane where an error occurs;
in response to the number being greater than the predetermined number, determine whether the current retry count is less than the predetermined count; and
in response to the current retry count being less than the predetermined count, perform the erase retry operation on the first physical unit belonging to the first physical plane, wherein the erase retry operation is a single plane operation.

22. The memory control circuit unit according to claim 21, wherein the memory management circuit is further configured to:
in response to the number not being greater than the predetermined number, update the first physical unit as a second-level error in a bad block table.

23. The memory control circuit unit according to claim 17, wherein the memory management circuit is further configured to:
in response to the current retry count not being less than the predetermined count, update the first physical unit as a second-level error in a bad block table.

24. The memory control circuit unit according to claim 17, wherein the memory management circuit is further configured to:
in response to the first operation failing, record the first physical unit as a first-level error in a bad block table.
